(19) United States
(12) Patent Application Publication
(10) Pub. No.: US 2005/0195573 A1
(43) Pub. Date: Sep. 8, 2005

(54) Heat dissipation module for a CPU

(76) Inventor: Ming Tang Huang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/791,883

(22) Filed: Mar. 4, 2004

(51) Int. Cl. H05K 7/20

(52) U.S. Cl. 361/709; 361/696; 361/704

(57) ABSTRACT

A heat dissipation module for a CPU has a heat dissipation device, a fan fixing frame, and a fan. The fan fixing frame can be fixed above the heat dissipation device. The fan fixing frame has a top plate, two side plates, a plurality of the elastic pressing components and at least one positioning elastic strip. The two side plates extend to form a pulling portion and a plurality of clipping portions. The elastic pressing components are installed on the top plate, the positioning elastic strip being installed on the top plate, and the positioning elastic trip forming at least two pushing portions to touch the outer surface of the two side plates. The fan is fixed on the top plate of the fan fixing frame. Some extra useful structures establish an easy to assemble and disassemble module with good related properties.

### FIELD OF THE INVENTION

The present invention relates to a kind of heat dissipation module for a CPU, and more particularly relates to an easily cleaned heat dissipation module with a good dissipation effect for attachment on the CPU.

### BACKGROUND OF THE INVENTION

Due to the progress of the computer industry, central processing units (CPU) are much faster. The heat dissipation rate of the CPU is also higher. For the purpose of transferring heat from CPU to the outside environment to achieve proper operating conditions, a heat dissipation device (such as heat sink) with high dissipation area is used. The heat dissipation device is installed in contact with the hot surface of CPU for cooling. In order to fix the heat dissipation device tightly on the CPU, a clipping mechanism is used.

Reference is made to FIG. 1 and FIG. 2, in which the conventional CPU 90 is installed on the Main Printed Circuit Board (MPCB) 91. The MPCB 91 includes a base socket 92 and the CPU 90 is installed on the base socket 92. The base socket 92 has a plurality of clipping arms 93 installed on opposite sides.

The heat dissipation mechanism 94 is installed on the CPU 90 and made of material with good heat conductivity. The heat dissipation mechanism 94 has a plurality of fins 95 to increase the heat-exchanging surface thereof. The middle area of the heat dissipation mechanism 94 has no fins 95 to form a concave channel 96. In addition, a fan 99 is installed on the heat dissipation mechanism 94.

The concave channel 96 is used to receive a clipping mechanism 97 and the clipping mechanism 97 has mating holes 98 in opposite sides to mate with the clipping arms 93 on opposite sides of the base socket 92. By the above arrangement on the structure, the clipping mechanism 97 can touch the surface of the heat dissipation mechanism 94 to force the heat dissipation mechanism 94 to attach tightly to the hot surface of the CPU 90 to assist the CPU 90 in dissipating heat at a higher efficiency.

But for operation of the above-described conventional heat dissipation module, the operator needs to push the mating holes 98 on two sides of the clipping mechanism to mate with the clipping arms 93 on two sides of the base socket 92. The pushing action is very hard, and is difficult for even a person skilled in the relevant field. The structure of the conventional art can make the heat dissipation module very hard to install and remove, making mass production difficult and more expensive. In addition, the conventional art is also difficult to wash and inefficient in heat exchange.

Thus we can learn from the above described that the above conventional heat dissipation module is obviously not convenient in practical application. An improvement is necessary in this technical area.

Certainly, the inventor of the present invention recognizes the above shortage should be corrected and special effort is paid to research in this field. The present invention is presented with reasonable cost and good effect to resolve the above problems.

### SUMMARY OF THE INVENTION

The main purpose of the present invention is to provide a heat dissipation module for a CPU, which heat dissipation module is easy to assemble and disassemble. Mass production of the heat dissipation module according to the present invention is easy and cheap.

Another purpose of the present invention is to provide a heat dissipation module for a CPU, which heat dissipation module is efficient and easily washed.

In view of the above purposes, the present invention provide a heat dissipation module for a CPU suitable for installation on a CPU and a base socket. The present invention comprises a heat dissipation device, having a plurality of heat dissipation fins, with flowing paths thereof being formed between the fins. A fan fixing frame is fixed above the heat dissipation device, the fan fixing frame having a top plate, two side plates, a plurality of the elastic pressing components and at least one positioning elastic strip. The two side plates are formed by extending from the two opposite side of top plate, the two side plates extending to form a pulling portion and a plurality of clipping portions, the elastic pressing components being installed on the top plate, the positioning elastic strip being installed on the top plate, and the positioning elastic trip forming at least two pushing portions to touch on the outer surface of the two side plates. A fan is fixed on the top plate of the fan fixing frame. The fan fixing frame is installed above the base socket by using the clipping portions to connect with the related clipping arms on the two sides of the base socket, the elastic pressing components having the elastic force to press the heat dissipation device onto the heat exhausting surface of the CPU.

The various objects and advantages of the present invention will be more readily understood from the following detailed description when read in conjunction with the appended drawing.

### BRIEF DESCRIPTION OF DRAWING

The foregoing aspects and many of the attendant advantages of this invention will be more readily appreciated as the same becomes better understood by reference to the following detailed description, when taken in conjunction with the accompanying drawings, wherein:

FIG. 1 shows a 3-dimensional exploded view of a first heat dissipation module of a CPU according to the prior art;

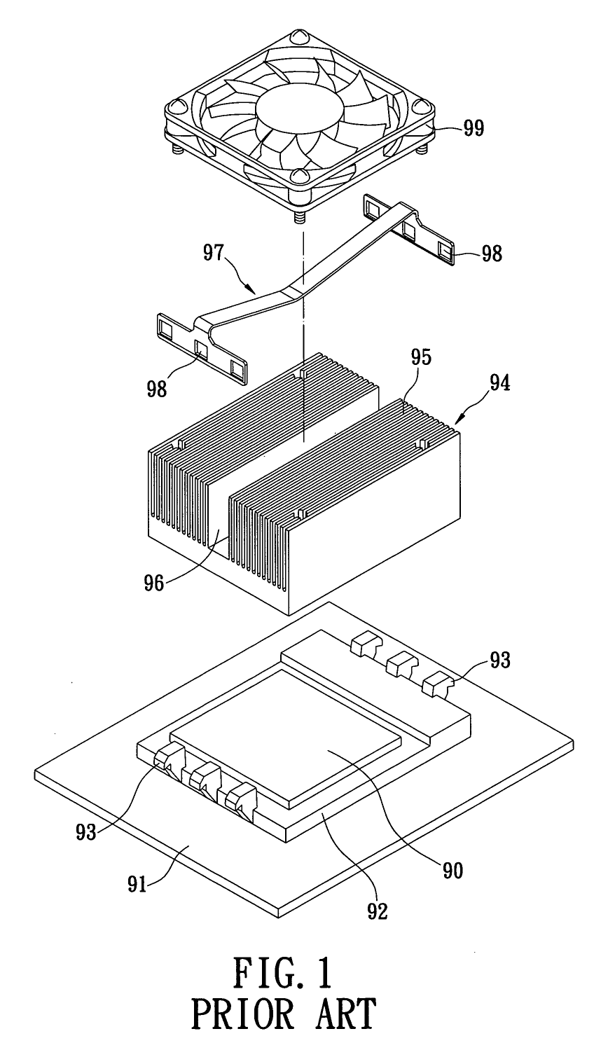

FIG. 2 shows a 3-dimensional assembled view of a first heat dissipation module of a CPU according to the prior art;

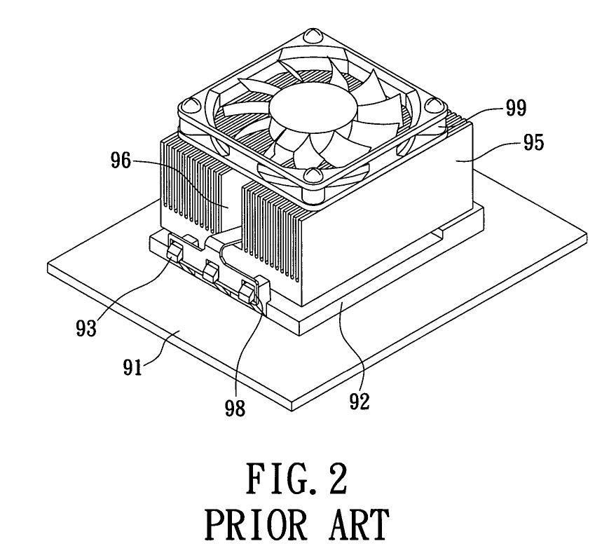

FIG. 3 shows a 3-dimensional exploded view of the present invention;

FIG. 4 shows a 3-dimensional assembled view of the present invention;

FIG. 5 shows a schematic view of the assembling progress (1) of the present invention;

FIG. 6 shows a schematic view of the assembling progress (2) of the present invention;

FIG. 7 shows a schematic view of the assembling progress (3) of the present invention;

FIG. 8 shows a 3-dimensional view of the fan-fixing frame of the present invention;

FIG. 9 shows another 3-dimensional view of the fan-fixing frame of the present invention;

FIG. 10 shows a 3-dimensional view of the heat dissipation device of the present invention; and

FIG. 11 shows another 3-dimensional view of the heat dissipation device of the present invention.

### DETAILED DESCRIPTION OF THE INVENTION

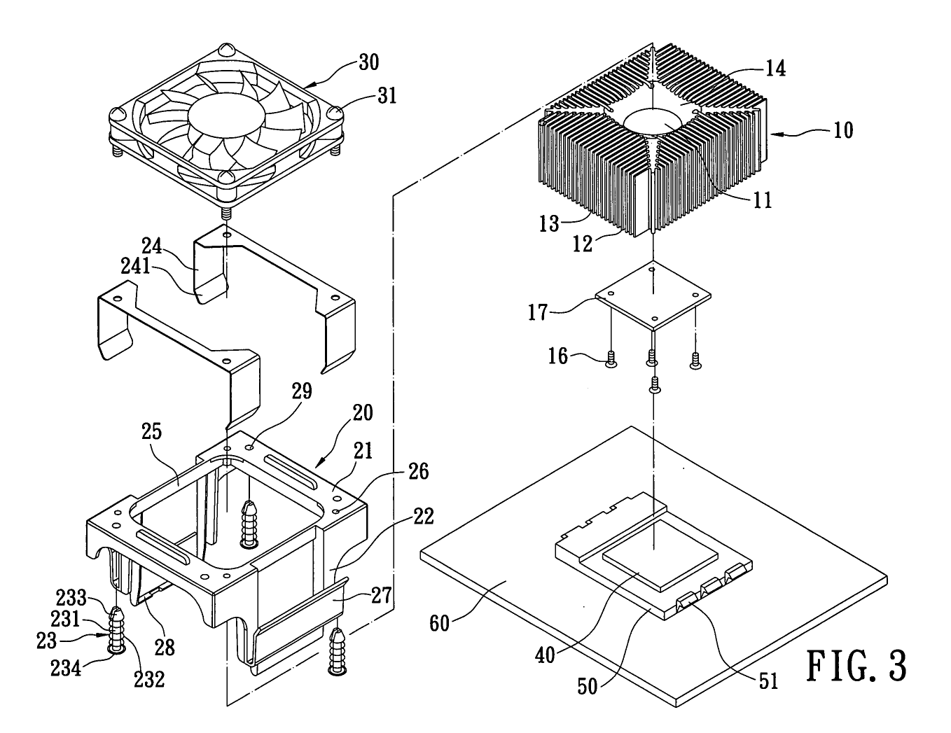

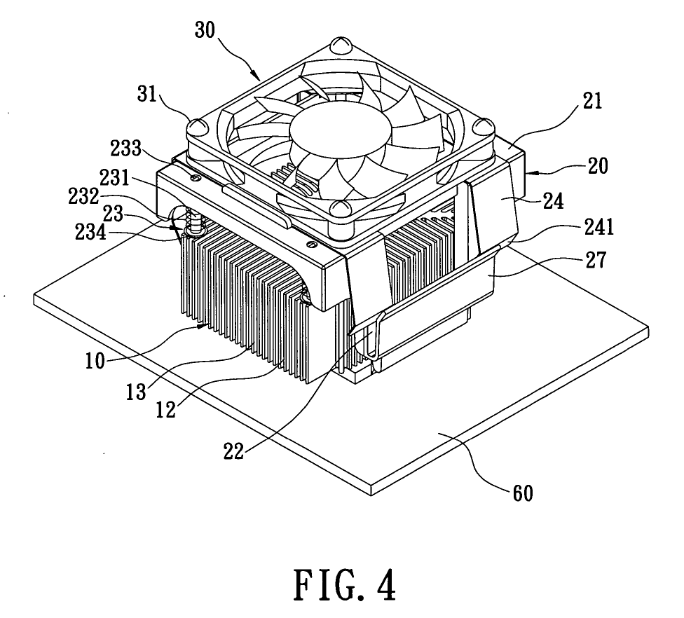

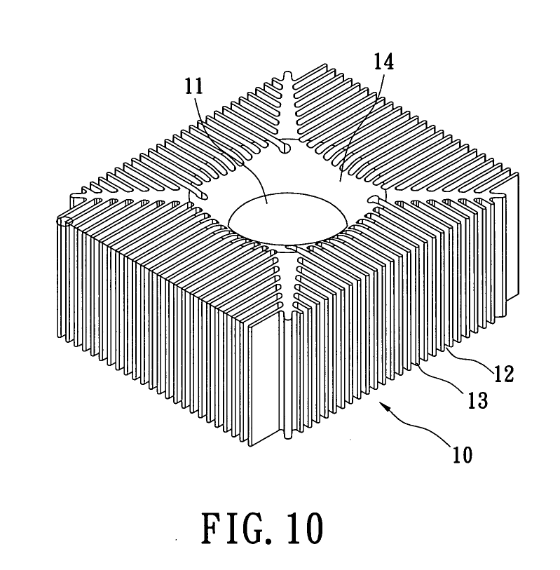

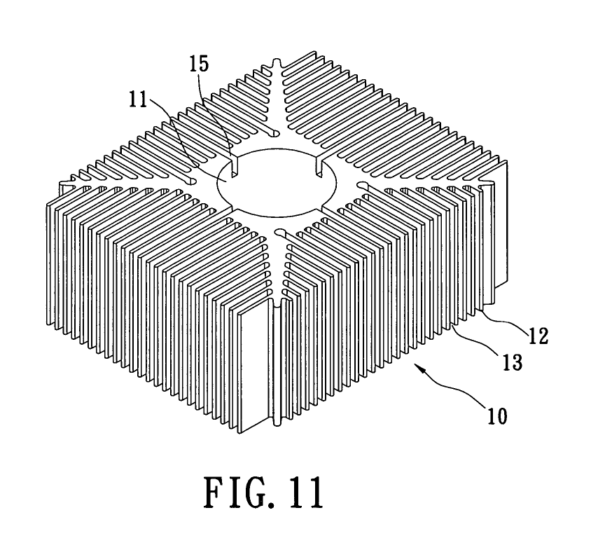

Reference is made to FIG. 3 and FIG. 4. The present invention provides a heat dissipation module for a CPU, and comprises a heat dissipation device 10, a fan fixing frame 20 and a fan 30. The heat dissipation device 10 is made of aluminum, copper or other metal material with good heat transferring ability. A through hole 11 in the middle of the heat dissipation device 10 is shown in FIG. 10 and FIG. 11. The through hole 11 penetrates the top and bottom of the heat dissipation device 10. A plurality of fins 12 are installed in the outer region of the through hole 11. In addition, a plurality of the flowing paths 13 are provide between the fins 12 for air flowing. The flowing paths 13 can connect the top portion, bottom portion, and the outside area of the heat dissipation device 10. The walls are in the opening shape at the top portion, bottom portion, and the outside area of the flowing paths 13.

Additionally, the through hole 11 has the air-flowing guiding surface 14 in an arced shape in the top area of the side surface. In the contrast, the through hole 11 has a plurality of air guiding holes 15 to connect with the flowing paths 13. Further, a heat transferring plate 17 is installed under the heat dissipation device 10 in relation to the through hole 11 by the screws 16. The heat transferring plate 17 is made of metal material with good heat-transferring ability such as aluminum or copper and is installed on the heat exhausting surface of the CPU 40.

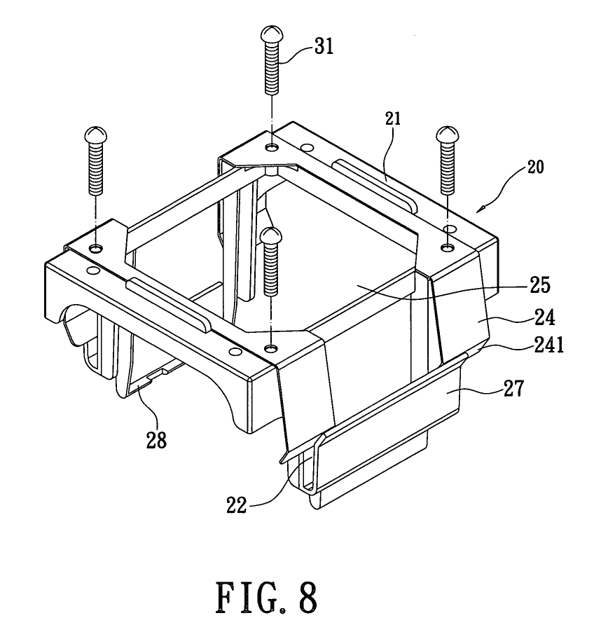

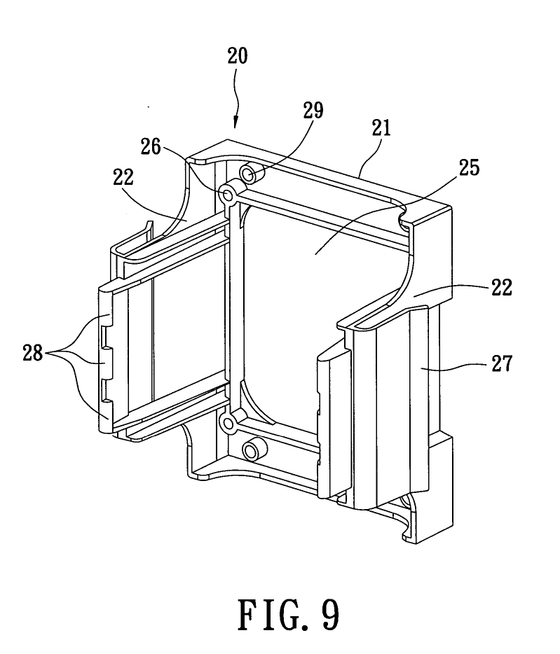

The fan fixing frame 20 is affixed to the heat dissipation device 10 by, for example, mechanical touch on the top area and the two side area of the heat dissipation device 10. The fan fixing frame 20 has a top plate 21, two side plates 22, a four elastic pressing components 23 and two positioning elastic strips 24 as shown in FIG. 8 and FIG. 9. The top plate 21 has an opening hole 25 and four connection holes 26. The fan 30 is installed on the top plate 21 and related to the opening hole 25 by the four screw 31 penetrating four corners of the top plate 21 within the four connection holes 26 to establish a screw connection between the fan 30 and the fan fixing frame 20.

The two side plates 22 are formed by extending from the two related side of the top plate 21 to the downward direction. The two side plates 22 also have the outside extending part to form a pulling portion 27. The pulling portion 27 has a free end on the upper side. The two side plates 22 have a plurality of clipping portions 28 extending downwardly. The clipping portions 28 are related to the clipping arms 51 on the two sides of the base socket 50. The clipping portions 28 of the present invention can be the shape of clipping hooks.

The elastic pressing components 23 comprises a connection part 231 and a spring 232. The connection part 231 has the hook portion 233 on the upper side and the pressing portion 234 on the lower side. The spring 232 is put around the connection part 231. The four connection parts 231 have the hook portion 233 installed on the piercing hole 29 on the top plate 21 of the fan fixing frame 20. The connection part 231 has the hook portion 233 with reversing-hook shape, and prevents the connection part 231 from escaping from the piercing hole 29 to fix the connection part 231 on the top plate 21 of the fan fixing frame 20. The spring 232 is located between the top plate 21 and the pressing portion 234 to provide the spring force to push the connection part 231 in a downward direction. The pressing portion 234 of the connection part 231 thus have an elastic force to press the heat dissipation device 10 onto the CPU 40 for heat exhausting.

The two positioning elastic strips 24 are made of metal material with good elastic property. The positioning elastic strips 24 are bent in the shape of an “n” and the positioning elastic strips 24 include a pushing portions 241 on two side thereof. The two positional elastic strips 24 can use the four screws 31 penetrating the fan 30 to be fixed on the top plate 21. The pushing portions 241 of the positioning elastic strips 24 can then be pushed to attach to the outer wall of the two side plates 22 to add a stiffer clipping force on the clipping portion 28 to make the same difficult to pull out. The embodiment illustrated in the figures have two positioning elastic strips 24, but one positioning elastic strip 24 is also possible in another embodiment. In the embodiment of one positioning elastic strip 24, the positioning elastic strip 24 has at least two pushing portions 241 to attach on the outer surface of the two side walls 22.

Reference is made to FIG. 3 to FIG. 7. The CPU 40 is usually installed on the main PCB 60 (printed circuit board) through the base socket 50. The socket base has a plurality of clipping arms 51 on opposite sides.

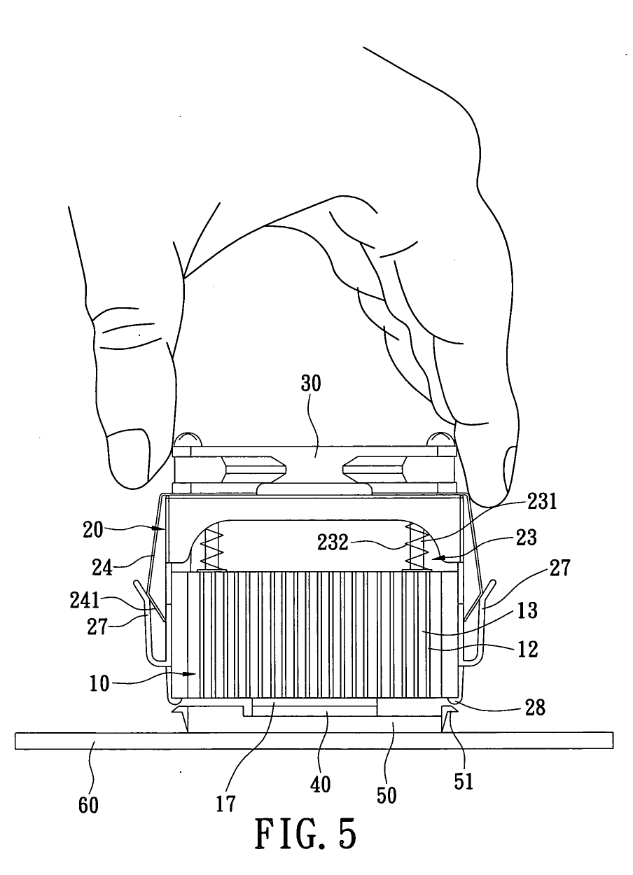

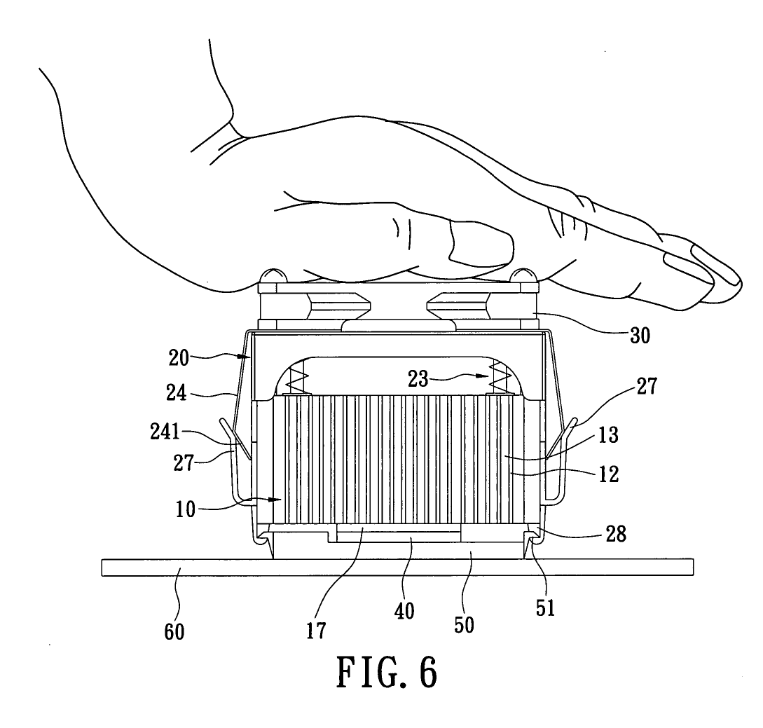

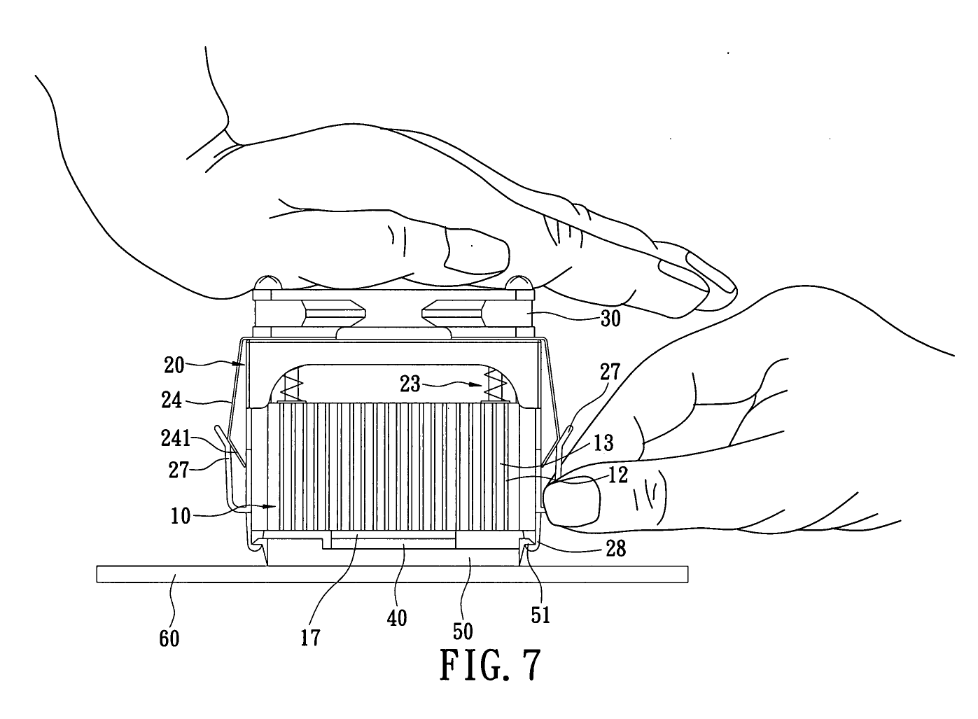

In the assembly stage, the heat dissipation device 10 is installed in a related location of base socket 50 (see FIG. 5), and then the fan fixing frame 20 is installed on the heat dissipation device 10 to let the clipping portions 28 thereof to clip on the clipping arm 51 of the base socket 50 (see FIG. 6). In the mating period, the elastic pressing components 23 elastically press the heat dissipation device 10 onto the CPU 40 to install the heat transferring plate 17 at the bottom of the heat dissipation device 10 in contact with the heat-exhausting surface of the CPU 40 for heat transfer from CPU 40. In the disassembly stage of the heat dissipation device 10, the operator presses the heat dissipation 10 and removes the clipping condition between the clipping portions 28 and the clipping arms 51 by pulling the pulling portion 27 out (see FIG. 7). The heat dissipation device 10 can then be removed from the base socket 50.

In addition, the present invention can use the fan 30 to induce the air above the fan 30 to flow from the upper side to the lower side to blow on the fins 12 of the heat dissipation device 10. The air flow can achieve the heat transfer and then drain through the lower side or outside the flowing path 13. The fan 30 can thus be used for heat dissipation of the heat dissipation device 10 for a CPU 40.

Further, the present invention provides the heat dissipation device 10 with a through hole 11 formed in the air-flowing guiding surface 14 to guide the upper cool air into the central area (at high temperatures) of the heat exhausting surface of the CPU 40. In addition, the incoming air is heated and then drains through the air guiding holes 15 in the side wall of the through hole 11 to avoid air interference between the incoming air and the outgoing air for good efficiency of heat dissipation.

Form the above description, it is apparent that the heat dissipation module for a CPU of the present invention is easily assembled and disassembled, thus reducing the cost of manual operation. The mass production of the present invention is easy and the heat dissipation ability thereof is very good.

In addition, the heat dissipation device 10 has the flowing paths 13 with opening shape on the bottom portion, top portion, and the outer side to achieve good heat dissipation ability and washing convenience.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

1. A heat dissipation module for a CPU, suitable for installation above the CPU and base socket, comprising:
a heat dissipation device, having a plurality of heat dissipation fins, flowing paths being formed between the fins;
a fan fixing frame, fixed above the heat dissipation device, the fan fixing frame having a top plate, two side plates, a plurality of the elastic pressing components and at least one positioning elastic strip, the two side plates extending from opposite sides of the top plate, the two side plates extending to form a pulling portion and a plurality of clipping portions, the elastic pressing components being installed on the top plate, the positioning elastic strip being installed on the top plate, and the positioning elastic trip forming at least two pushing portions to touch an outer surface of the two side plates; and
a fan fixed on the top plate of the fan fixing frame;
wherein the fan fixing frame is installed above the base socket by using the clipping portions to connect with related clipping arms on the two sides of the base socket, the elastic pressing components having the elastic force to press the heat dissipation device onto the heat exhausting surface of the CPU.

2. The heat dissipation module for a CPU as claimed in claim 1, wherein the heat dissipation device has a through hole with a shape feature of penetrating the heat dissipation device from top to bottom, the flowing paths having connection paths through the bottom, top and outer side of the heat dissipation device, a side wall of the through hole having an air-flowing guiding surface at a top area and a plurality of air guiding holes at a bottom area, the air guiding holes connecting with the flowing paths.

3. The heat dissipation module for a CPU as claimed in claim 2, wherein a heat transferring plate is installed in a bottom position to face the through hole of the heat dissipation device and contact the heat exhausting surface of the CPU.

4. The heat dissipation module for a CPU as claimed in claim 1, wherein the fan fixing frame has a opening hole and four connection holes, and the fan faces the opening hole and uses four screws to penetrate four corners of the fan fixing frame by screw connection at related connection holes.

5. The heat dissipation module for a CPU as claimed in claim 1, wherein the pulling portion of the fan fixing frame is formed by outer extension of the two side plates, the pulling portion having a free and upper end, the clipping portion being formed by downward extension of the two side plates.

6. The heat dissipation module for a CPU as claimed in claim 1, wherein the elastic pressing component comprises a connection part and a spring, the connection part having a hook portion on an upper side and a pressing portion on a lower side, the spring surrounding the connection part, the hook portion being inserted into a related piercing hole on the top plate of the fan fixing frame, and the spring being located between the top plate and the pressing portion.
